(19) United States
(12) Patent Application Publication
(10) Pub. No.: US 2026/0076038 A1
(43) Pub. Date: Mar. 12, 2026

(54) DISPLAY DEVICE

(71) Applicant: Samsung Display Co., LTD., Yongin-si (KR)

(72) Inventors: Shin Tack KANG, Yongin-si (KR); Seung Jun YU, Yongin-si (KR); Hyun Seok KIM, Yongin-si (KR)

(21) Appl. No.: 19/198,208

(22) Filed: May 5, 2025

(30) Foreign Application Priority Data
Sep. 9, 2024 (KR) 10-2024-0122521

(51) Int. Cl. H10K 59/122; G09G 3/32; G09G 3/3233; H10K 59/38; H10K 59/80

(52) U.S. Cl. CPC H10K 59/122; H10K 59/38; H10K 59/8792; G09G 3/32; G09G 3/3233; G09G 2300/0819; G09G 2300/0842

(57) ABSTRACT

A display device includes a substrate, a light emitting element layer on the substrate, and including a first light emitting area, a second light emitting area, and a third light emitting area, a thin-film encapsulation layer on the light emitting element layer, and a wavelength conversion layer on the thin-film encapsulation layer. The wavelength conversion layer includes a bank on the thin-film encapsulation layer and exposing the first light emitting area, the second light emitting area, and the third light emitting area, a reflective layer on a side surface of the bank, a light transmission pattern overlapping the first light emitting area, a first wavelength conversion pattern overlapping the second light emitting area, and a second wavelength conversion pattern overlapping the third light emitting area, and a capping layer on the bank, the light transmission pattern, the first wavelength conversion pattern, and the second wavelength conversion pattern.

This application claims priority to Korean Patent Application No. 10-2024-0122521, filed on Sep. 9, 2024, and all the benefits accruing therefrom under 35 U.S. C. § 119, the content of which in its entirety is herein incorporated by reference.

### BACKGROUND

### 1. Field

Embodiments of the disclosure relate to a display device.

### 2. Description of the Related Art

With the advance of information-oriented society, display devices for displaying images are widely used in various fields. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device include an organic light emitting display device composed of organic light emitting elements, an inorganic light emitting display device composed of inorganic light emitting elements such as inorganic semiconductors, and a micro light emitting display device composed of micro light emitting elements.

The organic light emitting element may include two opposing electrodes, and a light emitting layer interposed therebetween. The light emitting layer receives electrons and holes from the two electrodes and recombines the electrons and the holes to generate excitons, and the generated excitons change from an excited state to a ground state, thereby emitting light.

The organic light emitting display device including organic light emitting elements is attracting attention as a next-generation display device because of being able to meet the high display quality demands such as wide viewing angle, high brightness and contrast, and quick response speed as well as being able to be made having a low power consumption, lightweight, and thin by not including a separate light source such as a backlight unit.

### SUMMARY

Embodiments of the disclosure provide a display device that can effectively prevent color mixing and improve efficiency by increasing the particle concentration of a wavelength conversion layer.

According to one or more embodiments of the disclosure, a display device includes a substrate, a light emitting element layer disposed on the substrate, where the light emitting element layer includes a first light emitting area, a second light emitting area, and a third light emitting area, a thin-film encapsulation layer disposed on the light emitting element layer, and a wavelength conversion layer disposed on the thin-film encapsulation layer, where the wavelength conversion layer includes a bank disposed on the thin-film encapsulation layer, where the bank exposes the first light emitting area, the second light emitting area, and the third light emitting area, a reflective layer disposed on a side surface of the bank, a light transmission pattern overlapping the first light emitting area, a first wavelength conversion pattern overlapping the second light emitting area, and a second wavelength conversion pattern overlapping the third light emitting area, and a capping layer disposed on the bank, the light transmission pattern, the first wavelength conversion pattern, and the second wavelength conversion pattern.

In an embodiment, the bank may be in a reverse tapered shape.

In an embodiment, the bank may include an organic material and at least one selected from a light blocking dye or pigment.

In an embodiment, the reflective layer may be in contact with the side surface of the bank, and in contact with a side surface of each of the light transmission pattern, the first wavelength conversion pattern, and the second wavelength conversion pattern.

In an embodiment, a thickness of the light transmission pattern may be greater than a thickness of the bank, and a thickness of each of the first wavelength conversion pattern and the second wavelength conversion pattern may be smaller than the thickness of the bank.

In an embodiment, the first wavelength conversion pattern and the second wavelength conversion pattern may be in contact with the reflective layer and not in contact with the bank.

In an embodiment, the light transmission pattern may include a first base resin and a first scatter, the first wavelength conversion pattern may include a second base resin, a second scatterer, and a first wavelength shifter, and the second wavelength conversion pattern may include a third base resin, a third scatterer, and a second wavelength shifter.

In an embodiment, each of the first wavelength shifter and the second wavelength shifter may change light emitted from the light emitting element layer into light of a different color.

In an embodiment, the display device may further include a counter substrate disposed opposite to the substrate, a color filter layer disposed on the counter substrate, where the color filter layer includes a first color filter overlapping the first light emitting area, a second color filter overlapping the second light emitting area, and a third color filter overlapping the third light emitting area, and a filling layer disposed between the color filter layer and the wavelength conversion layer.

According to one or more embodiments of the disclosure, a display device includes a substrate, a light emitting element layer disposed on the substrate, where the light emitting element layer includes a first light emitting area, a second light emitting area, and a third light emitting area, a thin-film encapsulation layer disposed on the light emitting element layer, and a wavelength conversion layer disposed on the thin-film encapsulation layer, where the wavelength conversion layer includes a bank disposed on the thin-film encapsulation layer, where the bank exposes the first light emitting area, the second light emitting area, and the third light emitting area, a light transmission pattern overlapping the first light emitting area, a first wavelength conversion pattern overlapping the second light emitting area, and a second wavelength conversion pattern overlapping the third light emitting area, and a capping layer disposed on the bank, the first wavelength conversion pattern, and the second wavelength conversion pattern, and disposed between the light emission pattern and the thin-film encapsulation layer.

In an embodiment, the capping layer may be divided into portions separated and spaced apart on the bank.

In an embodiment, the light transmission pattern may be directly disposed on the capping layer, and not in direct contact with the bank.

In an embodiment, the bank may be in a reverse tapered shape.

In an embodiment, the bank may include an organic material and at least one selected from a light blocking dye or pigment.

According to one or more embodiments of the disclosure, a display device includes a substrate, a light emitting element layer disposed on the substrate, where the light emitting element layer includes a first light emitting area, a second light emitting area, and a third light emitting area, a thin-film encapsulation layer disposed on the light emitting element layer, and a wavelength conversion layer disposed on the thin-film encapsulation layer, where the wavelength conversion layer includes a bank disposed on the thin-film encapsulation layer, overlapping the first light emitting area, where the bank exposes the second light emitting area and the third light emitting area, a reflective layer disposed on a side surface of the bank, a first wavelength conversion pattern overlapping the second light emitting area and a second wavelength conversion pattern overlapping the third light emitting area, and a capping layer disposed on the bank, the first wavelength conversion pattern, and the second wavelength conversion pattern, wherein the bank includes a first base resin and a first scatterer.

In an embodiment, the bank may transmit light emitted from the light emitting element layer.

In an embodiment, the bank may be in a reverse tapered shape.

In an embodiment, the reflective layer may be in contact with the side surface of the bank, and in contact with a side surface of each of the first wavelength conversion pattern and the second wavelength conversion pattern.

In an embodiment, the first wavelength conversion pattern and the second wavelength conversion pattern may be in contact with the reflective layer and not in contact with the bank.

In an embodiment, the display device may further include a counter substrate disposed opposite to the substrate, a color filter layer disposed on the counter substrate, where the color filter layer includes a first color filter overlapping the first light emitting area, a second color filter overlapping the second light emitting area, and a third color filter overlapping the third light emitting area, and a filling layer disposed between the color filter layer and the wavelength conversion layer.

According to one or more embodiments of the disclosure, an electronic device, includes a display device which provides an image, and a processor which provides an image data signal to the display device, where the display device includes a substrate, a light emitting element layer disposed on the substrate, where the light emitting element includes a first light emitting area, a second light emitting area, and a third light emitting area, a thin-film encapsulation layer disposed on the light emitting element layer, and a wavelength conversion layer disposed on the thin-film encapsulation layer, where the wavelength conversion layer includes a bank disposed on the thin-film encapsulation layer, where the bank exposes the first light emitting area, the second light emitting area, and the third light emitting area, a reflective layer disposed on a side surface of the bank, a light transmission pattern overlapping the first light emitting area, a first wavelength conversion pattern overlapping the second light emitting area, and a second wavelength conversion pattern overlapping the third light emitting area, and a capping layer disposed on the bank, the light transmission pattern, the first wavelength conversion pattern, and the second wavelength conversion pattern.

In a display device according to an embodiment, color mixing between adjacent light emission areas may be effectively prevented by including a reflective layer on a side surface of a bank. In an embodiment, a light transmission pattern may be formed after forming a capping layer on first and second wavelength conversion patterns to prevent the first and second wavelength conversion patterns from being damaged during the process. In an embodiment, a bank including a first base resin and scatters may be formed so that the bank in a first light emitting area may function as a light transmission pattern and simplify a structure.

However, effects according to the embodiments of the disclosure are not limited to those exemplified above and various other effects are incorporated herein.

### BRIEF DESCRIPTION OF THE DRAWINGS

These and/or other features of embodiments of the disclosure will become apparent and more readily appreciated from the following description of the embodiments, taken in conjunction with the accompanying drawings in which:

FIG. 1 is a plan view of a display device according to an embodiment;

FIG. 2 is a schematic plan view illustrating lines included in the display device according to an embodiment;

FIG. 3 is an equivalent circuit diagram of a subpixel according to an embodiment;

FIG. 4 is a schematic cross-sectional view of the display device according to an embodiment;

FIG. 5 is a schematic cross-sectional view of the display device according to an embodiment;

FIGS. 6 to 10 are cross-sectional views illustrating a manufacturing method of a display device according to an embodiment;

FIG. 11 is a cross-sectional view of a display device according to another embodiment;

FIGS. 12 to 16 are cross-sectional views illustrating a manufacturing method of a display device according to another embodiment;

FIG. 17 is a cross-sectional view of a display device according to still another embodiment; and

FIGS. 18 to 21 are cross-sectional views illustrating a manufacturing method of a display device according to still another embodiment.

FIG. 22 is a block diagram of an electronic device according to one embodiment of the disclosure.

FIG. 23 is a schematic diagram of an electronic device according to various embodiments of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. The same reference numerals refer to the same components throughout the specification. The shapes, sizes, ratios, angles, numbers, etc. disclosed in the drawings for explaining the embodiments are example, and therefore the invention is not limited to the matters illustrated.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an. ” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Each of the features of the various embodiments of the invention may be partially or wholly combined or combined with each other, and various technical connections and operations are possible, and each embodiment may be implemented independently of each other or may be implemented together in a related relationship.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described with reference to the attached drawings.

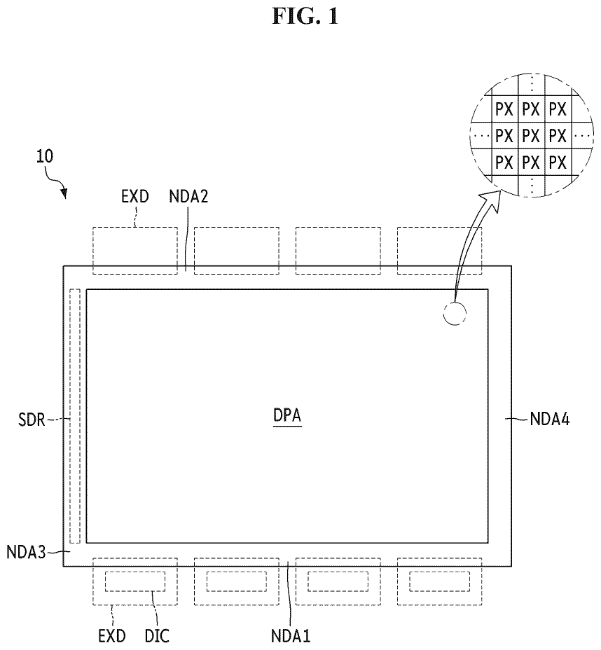

FIG. 1 is a plan view of a display device according to an embodiment.

Referring to FIG. 1, a display device 10 according to an embodiment may be applied to or included in smartphones, mobile phones, tablet personal computers (PCs), personal digital assistants (PDAs), portable multimedia players (PMPs), televisions, game consoles, wristwatch-type electronic devices, head mounted displays, monitors of PCs, laptop computers, car navigation systems, car dashboards, digital cameras, camcorders, outdoor billboards, electronic display boards, medical devices, examination devices, various home appliances such as refrigerators and washing machines, or Internet of things (IoT) devices. In the specification, embodiments where the display device 10 is a television will be described as an example, and the television may have high resolution or ultra-high resolution such as HD, UHD, 4K, or 8K.

In addition, the display device 10 according to an embodiment may be variously classified according to a display method. For example, the display device may be classified as an organic light emitting display device (OLED), an inorganic electroluminescent (EL) display device, a quantum dot light emitting display device (QED), a micro-light emitting diode display device, a nano-light emitting diode display device, a plasma display panel (PDP), a field emission display (FED) device, a cathode ray tube (CRT) display device, a liquid crystal display (LCD) device, or an electrophoretic display (EPD) device. Hereinafter, embodiments where the display device 10 is an organic light emitting display device and an inorganic EL display device will be described below as examples. Unless a special distinction is required, embodiments of the display device where the display device is an organic light emitting display device and an inorganic EL display device will be simply referred to as display devices. However, the embodiments are not limited to the organic light emitting display device or the inorganic EL display device, and other display devices listed above or known in the art can also be applied within the scope sharing the technical spirit.

The display device 10 according to an embodiment may have a quadrate shape, for example, a rectangular shape in a plan view. In an embodiment, where the display device 10 is a television, its long sides are located in a horizontal direction. However, the disclosure is not limited thereto, and the long sides may also be located in a vertical direction, or the display device 10 may be rotatably installed so that the long sides can be variably located in the horizontal or vertical direction.

The display device 10 may include a display area DPA and a non-display area NDA. The display area DPA may be an active area in which an image is displayed. The display area DPA may have a rectangular shape similar to the overall shape of the display device 10 in a plan view, but the disclosure is not limited thereto.

The display area DPA may include a plurality of pixels PX. The pixels PX may be arranged in a matrix form. Each of the pixels PX may be rectangular or square in a plan view. However, the disclosure is not limited thereto, and each of the pixels PX may also have a rhombus shape having each side inclined with respect to a side of the display device 10. The pixels PX may include various color pixels PX. In an embodiment, for example, the pixels PX may include, but are not limited to, first-color (red) pixels PX, second-color (green) pixels PX, and third-color (blue) pixels PX. These color pixels PX may be alternately arranged in a stripe or pentile™ type.

The non-display area NDA may be located around the display area DPA. The non-display area NDA may entirely or partially surround the display area DPA. The display area DPA may be rectangular, and the non-display area NDA may be adjacent to four sides of the display area DPA. The non-display area NDA may form or correspond to a bezel of the display device 10.

Driving circuits or driving elements for driving the display area DPA may be located in the non-display area NDA. In an embodiment, a pad unit may be provided on a display substrate of the display device 10 in a first non-display area NDA1 located adjacent to a first long side (a lower side in FIG. 1) of the display device 10 and a second non-display area NDA2 located adjacent to a second long side (an upper side in FIG. 1), and external devices EXD may be mounted on pad electrodes of the pad unit. Examples of the external devices EXD may include connection films, printed circuit boards, driving chips DIC, connectors, and wiring connection films. A scan driver SDR formed directly on the display substrate of the display device 10 may be located in a third non-display area NDA3 located adjacent to a first short side (a left side in FIG. 1) of the display device 10. However, the disclosure is not limited thereto, and the scan driver SDR may also be located on a second short side (a right side in FIG. 1) of the display device 10.

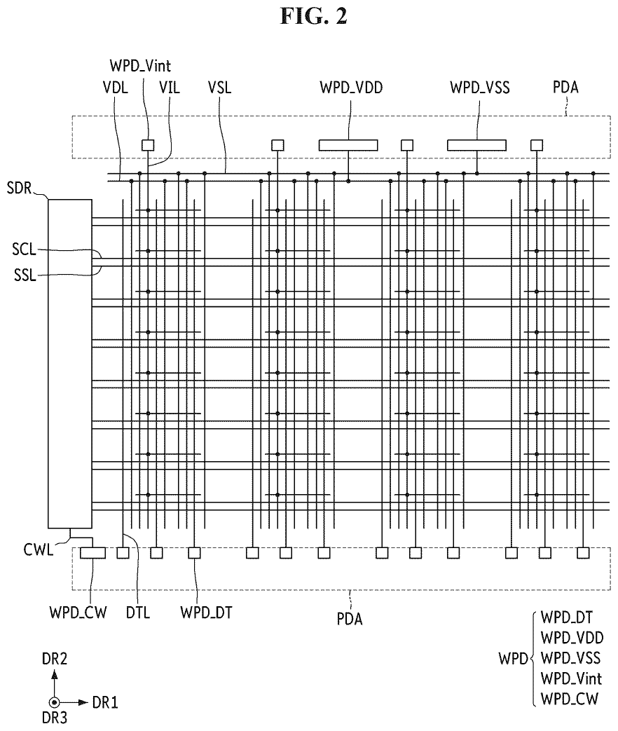

FIG. 2 is a schematic plan view illustrating lines included in the display device according to an embodiment.

Referring to FIG. 2, an embodiment of a display device 10 may include a plurality of lines. The lines may include scan lines SCL, sensing lines SSL, data lines DTL, initialization voltage lines VIL, a first voltage line VDL, and a second voltage line VSL. In addition, although not illustrated in the drawing, other lines may be further provided in the display device 10.

The scan lines SCL and the sensing lines SSL may extend in a first direction DR1. The scan lines SCL and the sensing lines SSL may be connected to the scan driver SDR. The scan driver SDR may include a driving circuit. The scan driver SDR may be located on a side of the display area DPA in the first direction DR1, but the disclosure is not limited thereto. The scan driver SDR may be connected to a signal connection line CWL, and at least one end of the signal connection line CWL may form a pad WPD_CW in a pad area PDA of the non-display area NDA and thus may be connected to an external device.

As used herein, the term “connect” may mean that any one member and another member are connected to each other not only through physical contact but also through another member. In addition, it can be understood that any one part and another part are connected to each other as one integrated member. Further, the connection between any one member and another member can be interpreted to include electrical connection through another member in addition to connection through direct contact.

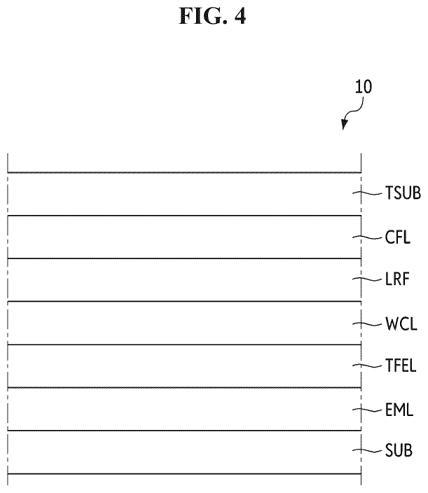

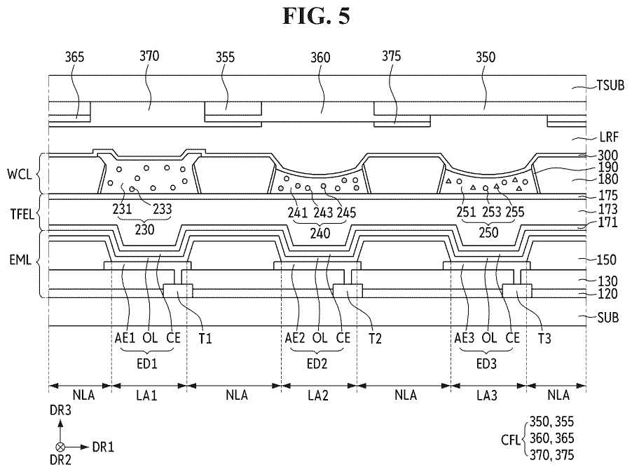

The data lines DTL and the initialization voltage lines VIL may extend in a second direction DR2 intersecting the first direction DR1. Each of the initialization voltage lines VIL may include a portion extending in the second direction DR2 and may further include portions branching from the above portion in the first direction DR1. Each of the first voltage line VDL and the second voltage line VSL may also include portions extending in the second direction DR2 and a portion connected to the above portions and extending in the first direction DR1. The first voltage line VDL and the second voltage line VSL may have a mesh structure, but the disclosure is not limited thereto. Although not illustrated in the drawing, each pixel PX of the display device 10 may be connected to at least one data line DTL, an initialization voltage line VIL, the first voltage line VDL, and the second voltage line VSL. In the disclosure, a third direction DR3 may be a direction perpendicular to a plane defined by the first direction DR1 and the second direction DR2, and the third direction DR3 may be a thickness direction of the display device 10 or a substrate SUB (shown in FIGS. 4 and 5) thereof.

The data lines DTL, the initialization voltage lines VIL, the first voltage line VDL, and the second voltage line VSL may be electrically connected to one or more wiring pads WPD. Each wiring pad WPD may be located in a pad area PDA. In an embodiment, wiring pads WPD_DT (hereinafter, referred to as ‘data pads’) of the data lines DTL may be located in a pad area PDA on a side of the display area DPA in the second direction DR2, and wiring pads WPD_Vint (hereinafter, referred to as ‘initialization voltage pads’) of the initialization voltage lines VIL, a wiring pad WPD_VDD (hereinafter, referred to as a ‘first power pad’) of the first voltage line VDL, and a wiring pad WPD_VSS (hereinafter, referred to as a ‘second power pad’) of the second voltage line VSL may be located in a pad area PDA located on the other side of the display area DPA in the second direction DR2. In another embodiment, the data pads WPD_DT, the initialization voltage pads WPD_Vint, the first power pad WPD_VDD, and the second power pad WPD_VSS may all be located in the same area, for example, in the non-display area NDA located on an upper side of the display area DPA. The external devices EXD may be mounted on the wiring pads WPD. The external devices EXD may be mounted on the wiring pads WPD through anisotropic conductive films, ultrasonic bonding, or the like.

Each pixel PX or subpixel of the display device 10 includes a pixel driving circuit. The above-described lines may transmit driving signals to each pixel driving circuit while passing through or around each pixel PX. The pixel driving circuit may include a transistor and a capacitor. The number of transistors and capacitors in each pixel driving circuit can be variously changed. According to an embodiment, the pixel driving circuit of each subpixel SPXn of the display device 10 may have a three-transistor-one-capacitor (3T1C) structure including three transistors and one capacitor. Although the pixel driving circuit is described below using the 3T1C structure as an example, the disclosure is not limited thereto, and other various modified pixel structures such as a two-transistor-one-capacitor (2T1C) structure, a seven-transistor-one-capacitor (7T1C) structure, and a six-transistor-one-capacitor (6T1C) structure are also applicable.

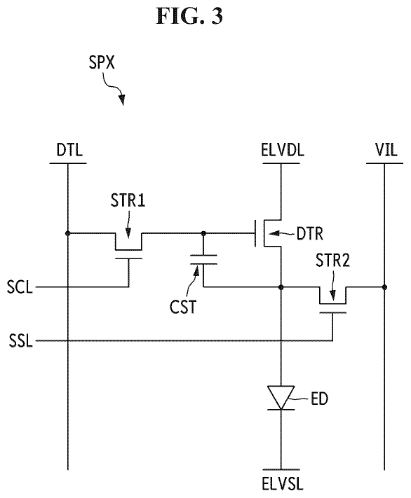

FIG. 3 is an equivalent circuit diagram of a subpixel according to an embodiment.

Referring to FIG. 3, each subpixel SPX of the display device 10 according to an embodiment includes three transistors DTR, STR1 and STR2 and one storage capacitor CST in addition to a light emitting element ED.

The light emitting element ED emits light corresponding to a current supplied through a driving transistor DTR. The light emitting element ED may be implemented as an inorganic light emitting diode, an organic light emitting diode, a micro-light emitting diode, or a nano-light emitting diode.

A first electrode (i.e., an anode electrode) of the light emitting element ED may be connected to a source electrode of the driving transistor DTR, and a second electrode (i.e., a cathode electrode) may be connected to a second power line ELVSL to which a low potential voltage (a second power supply voltage) lower than a high potential voltage (a first power supply voltage) of a first power line ELVDL is supplied.

The driving transistor DTR adjusts a current flowing from the first power line ELVDL, to which the first power supply voltage is supplied, to the light emitting element ED based on a voltage difference between a gate electrode and the source electrode. The driving transistor DTR may have the gate electrode connected to a first electrode of a first transistor STR1, the source electrode connected to the first electrode of the light emitting element ED, and a drain electrode connected to the first power line ELVDL to which the first power supply voltage is applied.

The first transistor STR1 is turned on by a scan signal of a scan line SCL to connect a data line DTL to the gate electrode of the driving transistor DTR. The first transistor STR1 may have a gate electrode connected to the scan line SCL, the first electrode connected to the gate electrode of the driving transistor DTR, and a second electrode connected to the data line DTL.

A second transistor STR2 is turned on by a sensing signal of a sensing signal line SSL to connect an initialization voltage line VIL to the source electrode of the driving transistor DTR. The second transistor STR2 may have a gate electrode connected to the sensing signal line SSL, a first electrode connected to the initialization voltage line VIL, and a second electrode connected to the source electrode of the driving transistor DTR.

In an embodiment, the first electrode of each of the first and second transistors STR1 and STR2 may be a source electrode, and the second electrode may be a drain electrode. However, the disclosure is not limited thereto, and the opposite may also be the case.

The capacitor CST is formed between the gate electrode and the source electrode of the driving transistor DTR. The storage capacitor CST stores a difference between a gate voltage and a source voltage of the driving transistor DTR.

The driving transistor DTR and the first and second transistors STR1 and STR2 may be formed as thin film transistors. In addition, although an embodiment where the driving transistor DTR and the first and second switching transistors STR1 and STR2 are N-type metal oxide semiconductor field effect transistors (MOSFETs) is shown in FIG. 3, the disclosure is not limited thereto. In another embodiment, the driving transistor DTR and the first and second switching transistors STR1 and STR2 may also be formed as P-type MOSFETs, or some of the driving transistor DTR and the first and second switching transistors STR1 and STR2 may be formed as N-type MOSFETs, and the other thereof may be formed as a P-type MOSFET.

FIG. 4 is a schematic cross-sectional view of the display device according to an embodiment.

Referring to FIG. 4, the display device 10 according to an embodiment may include a substrate SUB, a light emitting element layer EML, a thin-film encapsulation layer TFEL, a wavelength conversion layer WCL, a filling layer LRF, a color filter layer CFL, and a counter substrate TSUB.

The substrate SUB may be an insulating substrate. The substrate SUB may include a transparent material. In an embodiment, for example, the substrate SUB may include a transparent insulating material such as glass or quartz. The substrate SUB may be a rigid substrate. However, the disclosure is not limited thereto, and the substrate SUB may also include plastic such as polyimide or may have flexible characteristics so that it can be curved, bent, folded, or rolled.

The light emitting element layer EML may be located on the substrate SUB. The light emitting element layer EML may include a plurality of switching elements and a plurality of light emitting elements ED located in each subpixel. The switching elements may drive the light emitting elements ED so that the light emitting elements ED can emit light.

The thin-film encapsulation layer TFEL may be located on the light emitting element layer EML. The thin-film encapsulation layer TFEL may include an organic film located between a plurality of inorganic films to protect the light emitting element layer EML from external moisture and oxygen.

The wavelength conversion layer WCL may be located on the thin-film encapsulation layer TFEL. The wavelength conversion layer WCL may convert the wavelength of light emitted from the light emitting element layer EML to output red light, green light, and blue light.

The filling layer LRF may be located on the wavelength conversion layer WCL. The filling layer LRF may improve light efficiency by totally reflecting light emitted from the wavelength conversion layer WCL at an interface with the wavelength conversion layer WCL. The filling layer LRF may include a low-refractive material according to embodiments to be described later.

The color filter layer CFL may be located on the filling layer LRF. The color filter layer CFL may filter light incident from the outside to reduce reflection of the external light and may improve the color characteristics of light emitted through the wavelength conversion layer WCL.

The counter substrate TSUB may be located on the color filter layer CFL. The counter substrate TSUB may encapsulate the light emitting element layer EML together with the substrate SUB. The counter substrate TSUB may include a transparent material. In an embodiment, for example, the counter substrate TSUB may include a transparent insulating material such as glass or quartz.

FIG. 5 is a schematic cross-sectional view of the display device according to an embodiment.

Referring to FIG. 5, a display device 10 according to an embodiment may include the substrate SUB, the light emitting element layer EML, the thin-film encapsulation layer TFEL, the wavelength conversion layer WCL, the filling layer LRF, the color filter layer CFL, and the counter substrate TSUB.

A plurality of light emitting areas LA1 through LA3 and a non-light emitting area NLA may be defined on the substrate SUB. The light emitting areas LA1 through LA3 may be areas where light generated by light emitting elements ED1 through ED3 is emitted to the outside, and the non-light emitting area NLA may be an area where light is not emitted to the outside. In an embodiment, a first light emitting area LA1, a second light emitting area LA2, and a third light emitting area LA3 may be sequentially and repeatedly arranged along the first direction DR1 in the display area DPA.

The first light emitting area LA1, the second light emitting area LA2, and the third light emitting area LA3 may have different widths measured in the first direction DR1. In an embodiment, for example, the width of the first light emitting area LA1 may be smaller than the width of the third light emitting area LA3, and the width of the third light emitting area LA3 may be smaller than the width of the second light emitting area LA2. However, the disclosure is not limited thereto, and the first light emitting area LA1, the second light emitting area LA2 and the third light emitting area LA3 may have a same width measured in the first direction DR1.

The light emitting areas LA1 through LA3 may emit light of different colors. In an embodiment, the first light emitting area LA1 may emit light of a first color, the second light emitting area LA2 may emit light of a second color, and the third light emitting area LA3 may emit light of a third color. In an embodiment, the light of the first color may be blue light having a peak wavelength in a range of about 440 nanometers (nm) to about 480 nm, and the light of the second color may be red light having a peak wavelength a the range of about 610 nm to about 650 nm. In addition, the light of the third color may be green light having a peak wavelength in a range of about 510 nm to about 550 nm. However, the disclosure is not limited thereto, and the light of the second color may also be green light, and the light of the third color may also be red light.

Switching elements T1 through T3 may be located on the substrate SUB. In an embodiment, a first switching element T1 may be located on the substrate SUB in the first light emitting area LA1, a second switching element T2 may be located in the second light emitting area LA2, and a third switching element T3 may be located in the third light emitting area LA3. However, the disclosure is not limited thereto. In an embodiment, at least one selected from the first switching element T1, the second switching element T2, and the third switching element T3 may be located in the non-light emitting area NLA.

In an embodiment, each of the first switching element T1, the second switching element T2, and the third switching element T3 may be a thin-film transistor including amorphous silicon, polysilicon, or an oxide semiconductor. Although not illustrated in the drawings, a plurality of signal lines (e.g., gate lines, data lines, power lines, etc.) which transmit signals to each switching element may be further located on the substrate SUB. In addition, each of the switching elements T1 through T3 may include a first insulating layer 120. In an embodiment, for example, the first insulating layer 120 may be a gate insulating film or an interlayer insulating film of a thin-film transistor. The gate insulating film or the interlayer insulating film may be a single layer or a multilayer including at least one selected from silicon oxide (SiOx), silicon nitride oxide (SiOxNy), and silicon nitride (SiNx).

A second insulating layer 130 may be disposed on the first switching element T1, the second switching element T2, and the third switching element T3. In an embodiment, the second insulating layer 130 may be a planarization layer. In an embodiment, the second insulating layer 130 may include or be made of an organic film. In an embodiment, for example, the second insulating layer 130 may include acrylic resin, epoxy resin, imide resin, or ester resin. In an embodiment, the second insulating layer 130 may include a positive photosensitive material or a negative photosensitive material.

A first anode AE1, a second anode AE2, and a third anode AE3 may be located on the second insulating layer 130. The first anode AE1 may be located in the first light emitting area LA1, but at least a portion of the first anode AE1 may extend to the non-light emitting area NLA. The second anode AE2 may be located in the second light emitting area LA2, but at least a portion of the second anode AE2 may extend to the non-light emitting area NLA. The third anode AE3 may be located in the third light emitting area LA3, but at least a portion of the third anode AE3 may extend to the non-light emitting area NLA. The first anode AE1 may penetrate (or be disposed through) the second insulating layer 130 and may be connected to the first switching element T1. The second anode AE2 may penetrate the second insulating layer 130 and may be connected to the second switching element T2. The third anode AE3 may penetrate the second insulating layer 130 and may be connected to the third switching element T3.

In an embodiment, widths or areas of the first anode AE1, the second anode AE2, and the third anode AE3 may be different from each other. In an embodiment, for example, the width of the first anode AE1 may be smaller than the width of the second anode AE2, and the width of the third anode AE3 may be smaller than the width of the second anode AE2 and greater than the width of the first anode AE1. Alternatively, the area of the first anode AE1 may be smaller than the area of the second anode AE2, and the area of the third anode AE3 may be smaller than the area of the second anode AE2 and larger than the area of the first anode AE1. Alternatively, the area of the first anode AE1 may be smaller than the area of the second anode AE2, and the area of the third anode AE3 may be larger than the area of the second anode AE2 and the area of the first anode AE1. However, the disclosure is not limited to the above-described embodiment. In an embodiment, the widths or areas of the first anode AE1, the second anode AE2, and the third anode AE3 may be substantially the same as each other.

The first anode AE1, the second anode AE2, and the third anode AE3 may be reflective electrodes. The first anode AE1, the second anode AE2, and the third anode AE3 may have a stacked structure of a material layer having a high work function including indium tin oxide (ITO), indium zinc oxide (IZO), zinc oxide (ZnO), indium tin zinc oxide (ITZO) or indium oxide (In₂O₃), for example, and a reflective material layer including silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof, for example. The material layer having a high work function may be located on the reflective material layer so that the material layer having a high work function is located closer to a light emitting layer OL that the reflective material layer is. The first anode AE1, the second anode AE2, and the third anode AE3 may have, but are not limited to, a multilayer structure of ITO/Mg, ITO/MgF, ITO/Ag, or ITO/Ag/ITO.

A pixel defining layer 150 may be located on the first anode AE1, the second anode AE2, and the third anode AE3. The pixel defining layer 150 may be provided with an opening exposing the first anode AE1, an opening exposing the second anode AE2 and an opening exposing the third anode AE3 and may define the first light emitting area LA1, the second light emitting area LA2, the third light emitting area LA3 and the non-light emitting area NLA. That is, an area of the first anode AE1 which is exposed without being covered by the pixel defining layer 150 may be the first light emitting area LA1. An area of the second anode AE2 which is exposed without being covered by the pixel defining layer 150 may be the second light emitting area LA2. An area of the third anode AE3 which is exposed without being covered by the pixel defining layer 150 may be the third light emitting area LA3. In addition, an area where the pixel defining layer 150 is located may be the non-light emitting area NLA.

The pixel defining layer 150 may include an organic insulating material such as polyacrylates resin, epoxy resin, phenolic resin, polyamides resin, polyimides resin, unsaturated polyesters resin, polyphenylenes resin, polyphenylenesulfides resin, or benzocyclobutene (BCB).

In an embodiment, the pixel defining layer 150 may overlap a bank 180 of the wavelength conversion layer WCL, which will be described later, in the third direction DR3. The light emitting layer OL may be located on the first anode AE1, the second anode AE2, and the third anode AE3. In an embodiment in which the display device 10 is an organic light emitting display device, the light emitting layer OL may include an organic layer including an organic material. The organic layer includes an organic light emitting layer, and in some cases, may further include at least one of a hole injection layer, a hole transport layer, an electron transport layer, and an electron injection layer as an auxiliary layer that assists light emission.

In an embodiment, the light emitting layer OL may have a tandem structure including a plurality of organic light emitting layers overlapping each other in a thickness direction and a charge generation layer located between them. The organic light emitting layers overlapping each other may emit light of the same wavelength or may emit light of different wavelengths. In an embodiment, for example, the organic light emitting layers overlapping each other may include an organic light emitting layer that emits light of a green wavelength and an organic light emitting layer that emits light of a blue wavelength. In an embodiment, the organic light emitting layers overlapping each other may include an organic light emitting layer that emits light of a red wavelength, an organic light emitting layer that emits light of a green wavelength, and an organic light emitting layer that emits light of a blue wavelength.

In an embodiment, the light emitting layer OL may be in the shape of a continuous layer formed over the light emitting areas LA1 through LA3 and the non-light emitting area NLA. In such an embodiment, the wavelength of light emitted from the light emitting layer OL in the light emitting areas LA1 through LA3 may be the same as each other. In an embodiment, for example, the light emitting layer OL may emit blue light, light of a white wavelength, or ultraviolet light in the light emitting areas LA1 through LA3.

A cathode CE may be located on the light emitting layer OL. In an embodiment, the cathode CE may have translucency or transparency. In an embodiment where the cathode CE has translucency, the cathode CE may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg). In an embodiment, where a thickness of the cathode CE is tens to hundreds of angstroms, the cathode CE may have translucency.

In an embodiment, where the cathode CE has transparency, the cathode CE may include a transparent conductive oxide (TCO). In an embodiment, for example, the cathode CE may include tungsten oxide (WxOx), titanium oxide (TiO₂), indium tin oxide (ITO), indium zinc oxide (IZO), zinc oxide (ZnO), indium tin zinc oxide (ITZO), or magnesium oxide (MgO).

The first anode AE1, the light emitting layer OL, and the cathode CE may form (or collectively define) a first light emitting element ED1. The second anode AE2, the light emitting layer OL, and the cathode CE may form a second light emitting element ED2. The third anode AE3, the light emitting layer OL, and the cathode CE may form a third light emitting element ED3. Each of the first light emitting element ED1, the second light emitting element ED2, and the third light emitting element ED3 may emit source light, and the source light may be provided to the wavelength conversion layer WCL. The source light may be, for example, blue light. However, the disclosure is not limited thereto, and the source light may also be white light or ultraviolet light. The first light emitting element ED1, the second light emitting element ED2, and the third light emitting element ED3 may be organic light emitting diodes.

The thin-film encapsulation layer TFEL may be located on the cathode CE. The thin-film encapsulation layer TFEL may be commonly located in the first light emitting area LA1, the second light emitting area LA2, the third light emitting area LA3, and the non-light emitting area NLA. In an embodiment, the thin-film encapsulation layer TFEL may directly cover the cathode CE.

In an embodiment, the thin film encapsulation layer TFEL may include a first encapsulating inorganic film 171, an encapsulating organic film 173, and a second encapsulating inorganic film 175 sequentially stacked on the cathode CE.

The first encapsulating inorganic film 171 and the second encapsulating inorganic film 175 may each include at least one selected from silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and lithium fluoride. The encapsulating organic film 173 may include acrylic resin, methacrylate resin, polyisoprene, vinyl resin, epoxy resin, urethane resin, cellulose resin, or perylene resin.

However, the structure of the thin film encapsulation layer TFEL is not limited to the above example, and the stacked structure of the thin-film encapsulation layer TFEL can be variously changed.

The wavelength conversion layer WCL may be located on the light emitting element layer EML including the thin-film encapsulation layer TFEL.

The wavelength conversion layer WCL may include the bank 180, a reflective layer 190, a light transmission pattern 230, a first wavelength conversion pattern 240, a second wavelength conversion pattern 250, and a capping layer 300.

The bank 180 may be located on the thin-film encapsulation layer TFEL. The bank 180 may define the light emitting areas LA1 through LA3 and the non-light emitting area NLA. The bank 180 may overlap the non-light emitting area NLA to block transmission of light. In an embodiment, the bank 180 may be located between the light transmission pattern 230 and the first wavelength conversion pattern 240, between the first wavelength conversion pattern 240 and the second wavelength conversion pattern 250, and between the second wavelength conversion pattern 250 and the light transmission pattern 230 to effectively prevent color mixing between neighboring light emitting areas.

The bank 180 may be formed in a reverse tapered shape in a cross-section. In an embodiment, for example, the bank 180 may be formed in a shape having width of the lower side (or lower surface) to be smaller than the width of the upper side (or upper surface), and the edge of the upper side may be partially bent, chamfered or be rounded. However, the disclosure is not limited thereto, and the edge of the upper side may be formed to be pointed.

The bank 180 may include an organic light blocking material and may be formed through a process of coating and exposing the organic light blocking material or an inkjet method. In an embodiment, for example, the bank 180 may include an organic material and a light blocking dye or pigment mixed with the organic material. Examples of the organic material may include acrylic resin, methacrylate resin, polyisoprene, vinyl resin, epoxy resin, urethane resin, cellulose resin, and perylene resin. Examples of the dye or pigment may include carbon black.

The reflective layer 190 may be located on a side of the bank 180. The reflective layer 190 may serve to prevent light emitted within an area partitioned by the bank 180 from penetrating (or passing) into an adjacent light emitting area and causing color mixing. The reflective layer 190 may extend from the top surface of the second encapsulating inorganic film 175 to the side of the bank 180 and may be located to be spaced apart from the top surface of the bank 180. In an embodiment, for example, the height of the reflective layer 190 may be smaller than the height of the bank 180. The reflective layer 190 may contact and surround the side (or side surfaces) of the light transmission pattern 230, the side of the first wavelength conversion pattern 240, and the side of the second wavelength conversion pattern 250.

The reflective layer 190 may include a reflective material, for example, a reflective metal. The reflective layer 190, for example, may include silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof.

The light transmission pattern 230 may be located on the thin-film encapsulation layer TFEL. The light transmission pattern 230 may overlap the first light emitting area LA1 in the third direction DR3. The light transmission pattern 230 may transmit incident light. When source light provided from the first light emitting element ED1 is blue light, the blue source light may pass through the light transmission pattern 230.

In an embodiment, the light transmission pattern 230 may include a first base resin 231 and may further include first scatterers 233 dispersed in the first base resin 231.

The first base resin 231 may be made of a material having relatively high light transmittance. In an embodiment, the first base resin 231 may include or be made of an organic material. In an embodiment, for example, the first base resin 231 may include an organic material such as epoxy resin, acrylic resin, cardo resin, or imide resin.

The first scatterers 233 may have a refractive index different from that of the first base resin 231 and may form an optical interface with the first base resin 231. In an embodiment, for example, the first scatterers 233 may be light scattering particles. The first scatterers 233 are not particularly limited as long as the first scatterers 233 are formed of materials that can scatter at least a portion of transmitted light. However, the first scatterers 233 may be, for example, metal oxide particles or organic particles. The metal oxide may be, for example, titanium oxide (TiO₂), zirconium oxide (ZrO₂), aluminum oxide (Al₂O₃), indium oxide (In₂O₃), zinc oxide (ZnO) or tin oxide (SnO₂), and the organic particles may be made of, for example, acrylic resin or urethane resin. The first scatterers 233 may scatter incident light in random directions regardless of the incident direction of the incident light without substantially converting the wavelength of the incident light passing through the light transmission pattern 230.

In an embodiment, the light transmission pattern 230 may be formed by applying a photosensitive material and exposing and developing the photosensitive material. Accordingly, the thickness of the light transmission pattern 230 may be formed to be greater than the thickness of the bank 180. Here, the thickness may mean a width or a height measured from the top surface of the second encapsulating inorganic film 175 in the third direction DR3.

The first wavelength conversion pattern 240 and the second wavelength conversion pattern 250 may be located on the thin-film encapsulation layer TFEL.

The first wavelength conversion pattern 240 may be located on the thin-film encapsulation layer TFEL and may overlap the second light emitting area LA2 in the third direction DR3. The first wavelength conversion pattern 240 may be located in the area partitioned by the bank 180 and contact the side surface of the reflective layer 190 but not contact the bank 180. In an embodiment, for example, the thickness of the first wavelength conversion pattern 240 may be smaller than the thickness of the bank 180.

The first wavelength conversion pattern 240 may convert or shift the peak wavelength of incident light into another specific peak wavelength and output light of the specific peak wavelength. In an embodiment, the first wavelength conversion pattern 240 may convert source light provided from the second light emitting element ED2 into red light having a peak wavelength in a range of about 610 nm to 650 nm and may output the red light.

The first wavelength conversion pattern 240 may include a second base resin 241 and first wavelength shifters 245 dispersed in the second base resin 241 and may further include second scatterers 243 dispersed in the second base resin 241.

The second base resin 241 may include or be made of a material having high light transmittance. In an embodiment, the second base resin 241 may include or be made of an organic material. The second base resin 241 may include or be made of a same material as the first base resin 231 or may include at least one selected from the example materials of the first base resin 231 listed above.

The first wavelength shifters 245 may convert or shift the peak wavelength of incident light into another specific peak wavelength. In an embodiment, the first wavelength shifters 245 may convert source light (e.g., light of the first color which is blue light) provided from the second light emitting element ED2 into red light having a single peak wavelength in a range of about 610 nm to 650 nm and may output the red light.

The first wavelength shifters 245 may be, for example, quantum dots, quantum rods, or phosphors. In an embodiment, for example, the quantum dots may be particulate materials that emit light of a specific color when electrons transition from a conduction band to a valence band.

The quantum dots may be semiconductor nanocrystalline materials. The quantum dots may have a specific band gap according to their composition and size. Thus, the quantum dots may absorb light and then emit light having a unique wavelength. Examples of semiconductor nanocrystals of the quantum dots may include group IV nanocrystals, group II-VI compound nanocrystals, group III-V compound nanocrystals, group IV-VI nanocrystals, and combinations thereof.

Group II-VI compounds may be selected from binary compounds selected from CdSe, CdTe, ZnS, ZnSe, ZnTe, ZnO, HgS, HgSe, HgTe, MgSe, MgS and mixtures thereof; ternary compounds selected from InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and quaternary compounds selected from HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

Group III-V compounds may be selected from binary compounds selected from GaN, GaP, GaAs, GaSb, AlN, AlP, AlAs, AlSb, InN, InP, InAs, InSb and mixtures thereof; ternary compounds selected from GaNP, GaNAs, GaNSb, GaPAs, GaPSb, AlNP, AlNAs, AlNSb, AlPAs, AlPSb, InGaP, InNP, InAIP, InNAs, InNSb, InPAs, InPSb, GaAlNP and mixtures thereof; and quaternary compounds selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof.

Group IV-VI compounds may be selected from binary compounds selected from SnS, SnSe, SnTe, PbS, PbSe, PbTe and mixtures thereof; ternary compounds selected from SnSeS, SnSeTe, SnSTe, PbSeS, PbSeTe, PbSTe, SnPbS, SnPbSe, SnPbTe and mixtures thereof; and quaternary compounds selected from SnPbSSe, SnPbSeTe, SnPbSTe and mixtures thereof. Group IV elements may be selected from silicon (Si), germanium (Ge), and a mixture thereof. Group IV compounds may be binary compounds selected from silicon carbide (SiC), silicon germanium (SiGe), and a mixture thereof.

Here, the binary, ternary or quaternary compounds may be in particles at a uniform concentration or may be present in the same particles at partially different concentrations. In addition, they may have a core/shell structure in which one quantum dot surrounds another quantum dot. An interface between the core and the shell may have a concentration gradient in which the concentration of an element present in the shell is reduced toward the center.

In an embodiment, the quantum dots may have a core-shell structure including a core containing the above-described nanocrystal and a shell surrounding the core. The shell of each quantum dot may serve as a protective layer for maintaining semiconductor characteristics by preventing chemical denaturation of the core and/or as a charging layer for giving electrophoretic characteristics to the quantum dot. The shell may be a single layer or a multilayer. The shell of each quantum dot may be, for example, a metal or non-metal oxide, a semiconductor compound, or a combination thereof.

For example, the metal or non-metal oxide may be, but is not limited to, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ or NiO or a ternary compound such as MgAl₂O₄, CoFe₂O₄, NiFe₂O₄ or CoMn₂O₄.

In addition, the semiconductor compound may be, but is not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb.

Light emitted from the first wavelength shifters 245 may have a full width at half maximum (FWHM) of an emission wavelength spectrum of about 45 nm or less, about 40 nm or less, or about 30 nm or less. Therefore, the color purity and color reproducibility of the display device 10 can be further improved. In addition, the light emitted from the first wavelength shifters 245 may be radiated in various directions regardless of the incident direction of incident light. Therefore, the lateral visibility of the second color displayed in the second light emitting area LA2 can be improved.

A portion of the source light provided from the second light emitting element ED2 may not be converted into red light by the first wavelength shifters 245. However, the portion of the source light which is not converted into red light may be blocked by the color filter layer CFL located above the wavelength conversion layer WCL. On the other hand, red light into which the source light has been converted by the first wavelength conversion pattern 240 may be transmitted through the color filter layer CFL and then emitted to the outside.

The second scatterers 243 may have a refractive index different from that of the second base resin 241 and may form an optical interface with the second base resin 241. In an embodiment, for example, the second scatterers 243 may be light scattering particles. Other details of the second scatterers 243 are substantially the same as or similar to those of the first scatterers 233 described above, and thus any repetitive detailed description thereof will be omitted.

The second wavelength conversion pattern 250 may be located on the thin-film encapsulation layer TFEL and may overlap the third light emitting area LA3 in the third direction DR3. The second wavelength conversion pattern 250 may convert or shift the peak wavelength of incident light into another specific peak wavelength and output light of the specific peak wavelength. In an embodiment, the second wavelength conversion pattern 250 may convert source light provided from the third light emitting element ED3 into green light in a range of about 510 nm to about 550 nm and may output the green light.

The second wavelength conversion pattern 250 may include a third base resin 251 and second wavelength shifters 255 dispersed in the third base resin 251 and may further include third scatterers 253 dispersed in the third base resin 251.

The third base resin 251 may include or be made of a material having high light transmittance. In an embodiment, the third base resin 251 may include or be made of an organic material. The third base resin 251 may include or be made of the same material as the first base resin 231 or may include at least one selected from the example materials of the first base resin 231 listed above.

The second wavelength shifters 255 may convert or shift the peak wavelength of incident light to another specific peak wavelength. In an embodiment, the second wavelength shifters 255 may convert source light (e.g., blue light) having a peak wavelength in a range of about 440 nm to 480 nm into green light having a peak wavelength in a range of about 510 nm to 550 nm.

The second wavelength shifters 255 may be, for example, quantum dots, quantum rods, or phosphors. A more detailed description of the second wavelength shifters 255 is substantially the same as or similar to the above description of the first wavelength shifters 245 and thus any repetitive detailed description thereof will be omitted. In an embodiment, both the first wavelength shifters 245 and the second wavelength shifters 255 may be composed of or defined by quantum dots. In such an embodiment, the particle size of quantum dots that form the first wavelength shifters 245 may be larger than the particle size of quantum dots that form the second wavelength shifters 255.

The third scatterers 253 may have a refractive index different from that of the third base resin 251 and may form an optical interface with the third base resin 251. In an embodiment, for example, the third scatterers 253 may be light scattering particles. Other details of the third scatterers 253 are substantially the same as or similar to those of the second scatterers 243 described above, and thus any repetitive detailed description thereof will be omitted.

Source light emitted from the third light emitting element ED3 may be provided to the second wavelength conversion pattern 250, and the second wavelength shifters 255 may convert the source light emitted from the third light emitting element ED3 into green light having a peak wavelength in a range of about 510 nm to about 550 nm and may output the green light.

A portion of the source light may be transmitted through the second wavelength conversion pattern 250 without being converted into green light by the second wavelength shifters 255. However, the portion of the source light which is not converted into green light may be blocked by the color filter layer CFL. On the other hand, green light into which the source light has been converted by the second wavelength conversion pattern 250 may be transmitted through the color filter layer CFL and then emitted to the outside.

The above-described light transmission pattern 230 may be located to cover the reflective layer 190 and the bank 180. In an embodiment, for example, the light transmission pattern 230 may be located to cover the reflective layer 190 and a portion of the top surface of the bank 180. As will be described later, the light transmission pattern 230 may be formed through a photo process and located to cover the reflective layer 190 and the bank 180.

In an embodiment, the first wavelength conversion pattern 240 and the second wavelength conversion pattern 250 may each contact the reflective layer 190 and may not contact the bank 180. In another embodiment, the light transmission pattern 230, the first wavelength conversion pattern 240, and the second wavelength conversion pattern 250 may each cover the reflective layer 190 and may contact the side of the bank 180. As will be described later, the first wavelength conversion pattern 240 and the second wavelength conversion pattern 250 may be applied through an inkjet printing process and placed in the bank 180.

The capping layer 300 may be located on the bank 180, the reflective layer 190, the light transmission pattern 230, the first wavelength conversion pattern 240, and the second wavelength conversion pattern 250 to cover them. Therefore, the capping layer 300 may effectively prevent damage to or contamination of the bank 180, the reflective layer 190, the light transmission pattern 230, the first wavelength conversion pattern 240 and the second wavelength conversion pattern 250 by preventing penetration of impurities such as moisture or air from the outside.

The capping layer 300 may include or be made of an inorganic material. In an embodiment, for example, the capping layer 300 may include silicon nitride, aluminum nitride, zirconium nitride, titanium nitride, hafnium nitride, tantalum nitride, silicon oxide, aluminum oxide, titanium oxide, tin oxide, or silicon oxynitride.

According to an embodiment, by including the bank 180 in a reverse tapered shape and the reflective layer 190 at the side of the bank 180, it is possible to effectively prevent color mixing due to light penetrating into adjacent pixels from occurring.

The filling layer LRF may be located on the capping layer 300. The filling layer LRF may be located directly on the capping layer 300 and between the wavelength conversion layer WCL and the color filter layer CFL. The filling layer LRF may contact each of the wavelength conversion layer WCL and the color filter layer CFL. The filling layer LRF may entirely cover the top of the wavelength conversion layer WCL. The filling layer LRF may be located in the entire display area DPA (see FIG. 1) of the display device 10. In an embodiment, for example, the filling layer LRF may be located on the light emitting areas LA1 through LA3 and the non-light emitting area NLA in the display area DPA. In addition, the filling layer LRF may extend to the non-display area NDA (see FIG. 1) of the display device 10.

The filling layer LRF may have a relatively lower refractive index than the light transmission pattern 230, the first wavelength conversion pattern 240, the second wavelength conversion pattern 250, and the capping layer 300. The filling layer LRF may totally reflect some of the light emitted from the wavelength conversion layer WCL due to a difference in refractive index at an interface with the capping layer 300. The totally reflected light may re-enter the first wavelength conversion pattern 240 and the second wavelength conversion pattern 250 and be reused for wavelength conversion or may be re-reflected by the scatterers of the wavelength conversion layer WCL to the front. Therefore, the front light emission efficiency of the display device 10 including the filling layer LRF can be improved.

A thickness of the filling layer LRF may be in a range of about 0.1 micrometer (μm) to about 4.5 μm. If the thickness of the filling layer LRF is about 0.1 μm or more, the flatness of the filling layer LRF can be secured, and a gap with the color filter layer CFL can be easily formed. If the thickness of the filling layer LRF is about 4.5 μm or less, it is possible to prevent defects by preventing penetration of moisture or oxygen from the outside through the filling layer LRF. A refractive index of the filling layer LRF may be in a range of about 1.05 to about 1.4. If the refractive index of the filling layer LRF is about 1.05 or greater, a front side luminance ratio of the display device 10 can be increased. If the refractive index of the filling layer LRF is about 1.4 or less, a reduction in the front luminance efficiency of the display device 10 can be prevented.

The color filter layer CFL may be located on the wavelength conversion layer WCL, and the counter substrate TSUB may be located on the color filter layer CFL.

The color filter layer CFL may include a first color filter 350, a second color filter 360, and a third color filter 370. In addition, the color filter layer CFL may include a first color pattern 355, a second color pattern 365, and a third color pattern 375.

The first color filter 350 may be located between the counter substrate TSUB and the filling layer LRF and may overlap the third light emitting area LA3 in the third direction DR3. The first color filter 350 may overlap the third light emitting element ED3 and the second wavelength conversion pattern 250 in the third direction DR3. The first color pattern 355 may be spaced apart from the first color filter 350 and may overlap the non-light emitting area NLA in the third direction DR3. The first color filter 350 may directly contact the filling layer LRF.

The first color filter 350 and the first color pattern 355 may selectively transmit light of the third color (e.g., green light) and may block or absorb light of the first color (e.g., blue light) and light of the second color (e.g., red light). In an embodiment, the first color filter 350 may be a green color filter and may include a green colorant such as green dye or green pigment. As used herein, the term “colorant” is a concept encompassing both a dye and a pigment.

The second color filter 360 may be located between the counter substrate TSUB and the filling layer LRF and may overlap the second light emitting area LA2 in the third direction DR3. The second color filter 360 may overlap the second light emitting element ED2 and the first wavelength conversion pattern 240 in the third direction DR3. In an embodiment, a side of the second color filter 360 may overlap the non-light emitting area NLA and the adjacent first color filter 350 in the third direction DR3. The other side of the second color filter 360 may overlap the non-light emitting area NLA and the first color pattern 355 in the third direction DR3. The second color pattern 365 may be spaced apart from the second color filter 360 and may overlap the non-light emitting area NLA. The second color pattern 365 may overlap the first color filter 350 in the non-light emitting area NLA in the third direction DR3. The second color filter 360 may directly contact the filling layer LRF.

The second color filter 360 and the second color pattern 365 may selectively transmit light of the second color (e.g., red light) and may block or absorb light of the first color (e.g., blue light) and light of the third color (e.g., green light). In an embodiment, for example, the second color filter 360 may be a red color filter and may include a red colorant such as red dye or red pigment.

The third color filter 370 may be located between the counter substrate TSUB and the filling layer LRF and may overlap the first light emitting area LA1. The third color filter 370 may overlap the first light emitting element ED1 and the light transmission pattern 230 in the third direction DR3. In an embodiment, a side of the third color filter 370 may overlap the non-light emitting area NLA and the adjacent second color filter 360 in the third direction DR3. In addition, the other side of the third color filter 370 may overlap the non-light emitting area NLA in the third direction DR3 and may overlap an adjacent first color filter 350 and the second color pattern 365 in the third direction DR3. The third color pattern 375 may be spaced apart from the third color filter 370 and may overlap the non-light emitting area NLA in the third direction DR3. The third color pattern 375 may overlap the second color filter 360 in the non-light emitting area NLA in the third direction DR3. The third color filter 370 and the third color pattern 375 may directly contact the filling layer LRF.

The third color filter 370 may selectively transmit light of the first color (e.g., blue light) and may block or absorb light of the second color (e.g., red light) and light of the third color (e.g., green light). In an embodiment, for example, the third color filter 370 may be a blue color filter and may include a blue colorant such as blue dye or blue pigment.

In an embodiment, as described above, the first through third color filters 350, 360 and 370 and the first through third color patterns 355, 365 and 375 may overlap each other in the non-light emitting area NLA to block or absorb light. In an embodiment, for example, the first color pattern 355, the second color filter 360 and the third color filter 370 may overlap each other in the non-light emitting area NLA located on a side of the second light emitting area LA2, and the first color filter 350, the second color filter 360 and the third color pattern 375 may overlap each other in the non-light emitting area NLA located on the other side of the second light emitting area LA2.

A method of manufacturing the display device 10 according to an embodiment illustrated in FIG. 5 will now be described. In the following, the process of manufacturing the wavelength conversion layer WCL will be mainly described, and the other structures are as shown in FIG. 5. The formation process of each layer may be performed using a general patterning process or an inkjet process. Hereinafter, the formation method of each process will be briefly described and will be explained focusing on the formation sequence.

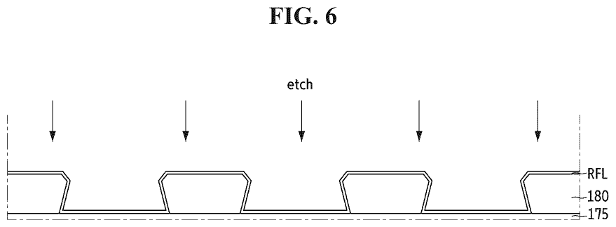

FIGS. 6 to 10 are cross-sectional views illustrating a manufacturing method of a display device according to an embodiment.

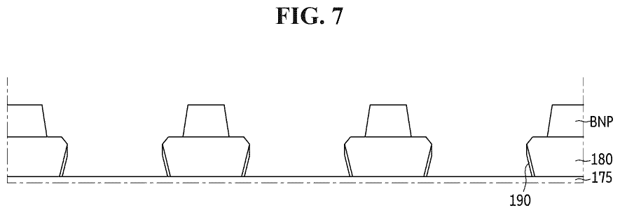

Referring to FIGS. 6 and 7, in an embodiment of a manufacturing method of a display device, a substrate SUB is prepared. The substrate SUB may be prepared as the light emitting element layer EML (see FIG. 5) and the thin-film encapsulation layer TFEL (see FIG. 5) are formed. In an embodiment, for example, the light emitting element layer EML (see FIG. 5) may be formed on the substrate SUB, and the thin-film encapsulation layer TFEL (see FIG. 5) may be formed on the light emitting element layer EML (see FIG. 5). For convenience of illustration and description, only a second encapsulating inorganic film 175 of the thin-film encapsulation layer TFEL is illustrated in FIGS. 6 to 10 and the description of the structure thereunder will be omitted.

In an embodiment of a manufacturing method of a display device, a bank 180 is formed on the second encapsulating inorganic film 175 of the thin-film encapsulation layer TFEL (see FIG. 5). The bank 180 may include a negative type material including an organic light blocking material. In an embodiment, for example, the bank 180 may be a negative photoresist. The bank 180 may be manufactured by coating a negative photoresist on the second encapsulating inorganic film 175 and exposing and developing it. The bank 180 may be formed in a reverse tapered shape as shown in FIG. 6.

Next, a reflective material layer RFL is formed on the bank 180. The reflective material layer RFL may be stacking a reflective material using a chemical or physical vapor deposition method. In an embodiment, for example, the reflective material layer RFL may be formed through a sputtering process. The reflective material layer RFL may be entirely deposited on the bank 180 and the second encapsulating inorganic film 175.

Subsequently, the reflective material layer RFL is etched to form a reflective layer 190. The reflective material layer RFL may be etched using an anisotropic dry etching process. The anisotropic dry etching process involves etching in the vertical direction in the drawing, and due to the reverse tapered shape, the rest of the reflective material layer RFL except for the side surfaces of the bank 180 may be etched and removed. In an embodiment, for example, the reflective layer 190 may be formed only on the side of the bank 180 as described above. Accordingly, in such an embodiment, the reflective layer 190 may be formed without using a mask.

Next, a photo pattern BNP is formed on the bank 180. The photo pattern BNP may include a positive photoresist including a liquid-repellent material. The photo pattern BNP may be manufactured, for example, by coating the positive photoresist, and exposing and developing it. The photo pattern BNP may be formed directly on the upper surface of the bank 180 and may be formed in a regular taper shape. In addition, the photo pattern BNP may be formed as the liquid-repellent material that floats on the top surface of the photo pattern BNP, and the top surface of the photo pattern BNP may exhibit liquid-repellent properties.

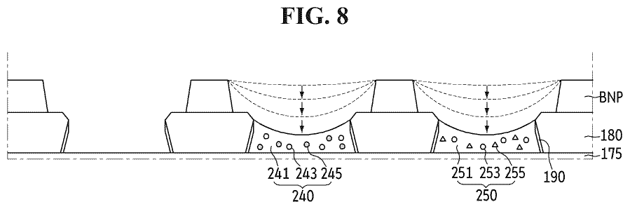

Next, referring to FIG. 8, a first wavelength conversion pattern 240 is formed in an area corresponding to the second light emitting area LA2 (see FIG. 5) and a second wavelength conversion pattern 250 is formed in an area corresponding to the third light emitting area LA3 (see FIG. 5).

In an embodiment, a first wavelength conversion material is applied in an area corresponding to the second light emitting area LA2 (see FIG. 5). The first wavelength conversion material may include a second base resin 241, first wavelength shifters 245, and second scatterers 243 dispersed in a solvent. The first wavelength conversion material may be applied through a solution process, such as an inkjet printing process. When the first wavelength conversion material is applied to a space divided by the bank 180 and a photo pattern BNP, the first wavelength conversion material may be applied to a thickness similar to the surface of the photo pattern BNP. In particular, the surface of the photo pattern BNP may exhibit liquid-repellent properties, thereby effectively preventing the first wavelength conversion material from overflowing into other spaces beyond the photo pattern BNP. Afterwards, when the solvent of the first wavelength conversion material is volatilized through heat treatment, the thickness is gradually reduced as shown in FIG. 8, and the first wavelength conversion pattern 240 may be finally formed through ultraviolet (UV) and/or heat curing.

Subsequently, a second wavelength conversion material is applied to an area corresponding to the third light emitting area LA3 (see FIG. 5). The second wavelength conversion material may include a third base resin 251, second wavelength shifters 255, and third scatterers 253 dispersed in the solvent. The second wavelength conversion material may be applied through a solution process, such as an inkjet printing process. The second wavelength conversion material is applied to a space partitioned by the bank 180 and the photo pattern BNP, heat treated in the same manner as the first wavelength conversion pattern 240 to volatilize the solvent, and then cured through UV and/or heat curing to finally form a second wavelength conversion pattern 250.

In FIG. 8, the first wavelength conversion pattern 240 and the second wavelength conversion pattern 250 are shown as manufactured simultaneously. However, as described above, the first wavelength conversion pattern 240 and the second wavelength conversion pattern 250 may be formed sequentially.

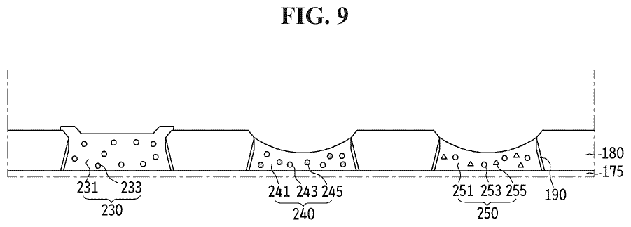

Next, referring to FIG. 9, the photo pattern BNP may be stripped and removed. The photo pattern BNP may include a positive type photoresist, so the strip process may be relatively easier than the negative type. Accordingly, it is possible to effectively prevent residues of the photo pattern BNP from occurring on the bank 180.

Subsequently, a light transmission pattern 230 may be formed in an area corresponding to the first light emitting area LA1 (see FIG. 5). The light transmission pattern 230 may be manufactured through a photo process unlike the first and second wavelength conversion patterns 240 and 250. In an embodiment, for example, a light transmitting material may be entirely coated on the bank 180 and the second encapsulating inorganic film 175 and then patterned by a photo process to form the light transmission pattern 230. The light transmitting material may include a first base resin 231 and first scatterers 233 dispersed in the solvent. The light transmission pattern 230 may be formed in a structure covering a portion of the top surface of the bank 180 by a photo process.

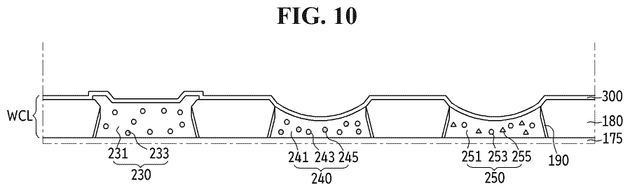

Next, referring to FIG. 10, a capping layer 300 is formed on the bank 180, the light transmission pattern 230, the first wavelength conversion pattern 240, and the second wavelength conversion pattern 250 to manufacture a wavelength conversion layer WCL. The capping layer 300 may be formed by stacking an inorganic insulating material entirely.

Thereafter, although not illustrated, a color filter layer CFL may be formed on a counter substrate TSUB and the counter substrate TSUB may be bonded to the wavelength conversion layer WCL through a filling layer LRF to manufacture a display device 10.

According to an embodiment, as the reflective layer 190 is formed using the bank 180 of an inverse tapered shape, the mask process may be omitted. In such an embodiment, a large amount of wavelength conversion materials can be applied by forming a photo pattern BNP using a positive photoresist and can be simply removed afterwards.

Hereinafter, other embodiments will be described with reference to other drawings.

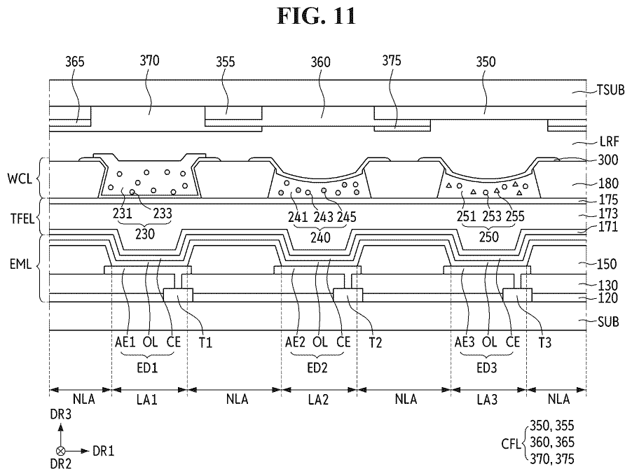

FIG. 11 is a cross-sectional view of a display device according to another embodiment. For example, FIG. 11 illustrates an embodiment of another structure in respect to a portion of FIG. 5.

The embodiment of FIG. 11 is substantially the same as the embodiment of FIG. 5 except that the capping layer 300 is not continuous and is separated, the reflective layer 190 is omitted, and the light transmission pattern 230 is located on the capping layer 300. Hereinafter, any repetitive detailed description of elements and features the same as those of FIG. 5 will be omitted, and differences will be described below.

In an embodiment, a bank 180 may be located on a thin-film encapsulation layer TFEL, and a first wavelength conversion pattern 240 may be formed in an area defined by the bank 180, for example, an area corresponding to the second light emitting area LA2, and a second wavelength conversion pattern 250 may be located in an area corresponding to the third light emitting area LA3.

A capping layer 300 may be located on the bank 180, the first wavelength conversion pattern 240, and the second wavelength conversion pattern 250. The capping layer 300 may be located not continuously and but separately on the bank 180. In an embodiment, for example, the capping layer 300 may be located on the bank 180 to partially expose the top surface of the bank 180. In addition, the capping layer 300 may be located in direct contact with the side of the bank 180 and the second encapsulating inorganic film 175 in an area corresponding to the first light emitting area LA1 and may be located between the second encapsulating inorganic film 175 and the light transmission pattern 230.

A light transmission pattern 230 may be located on the capping layer 300 in an area corresponding to the first light emitting area LA1. The light transmission pattern 230 may be placed directly on the capping layer 300 and may not contact the bank 180.

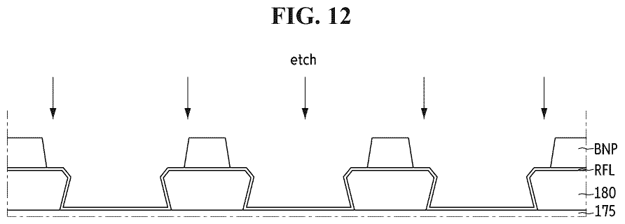

Hereinafter, a method of manufacturing a display device 10 illustrated in FIG. 11 will be described with reference to FIGS. 12 to 16. Any repetitive detailed description of the elements of the manufacturing method of FIGS. 6 to 10 the same as those described above will be omitted or simplified, and the differences will be mainly described.

FIGS. 12 to 16 are cross-sectional views illustrating a manufacturing method of a display device according to another embodiment.

Referring to FIG. 12, in an embodiment of a manufacturing method of a display device, a bank 180 is formed on a second encapsulating inorganic film 175 of the thin-film encapsulation layer TFEL (see FIG. 5), and a reflective material layer RFL is formed on the bank 180. A photo pattern BNP is formed on the reflective material layer RFL corresponding to the bank 180.

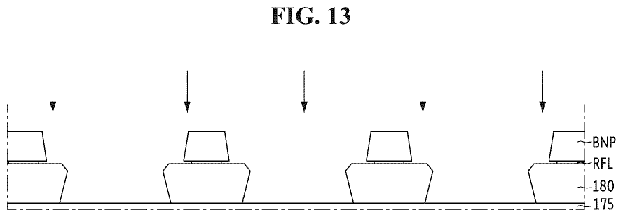

Subsequently, referring to FIG. 13, the reflective layer RFL is formed by etching the reflective material layer RFL. The reflective material layer RFL may be etched using a wet etching process. The area of the reflective material layer RFL not masked by the photo pattern BNP by using the photo pattern BNP as a mask may be etched and removed. In addition, due to the wet etching process, the reflective material layer RFL may be over-etched at the bottom of the photo pattern BNP, forming an undercut structure. In an embodiment, for example, the side surface of the photo pattern BNP may be formed to protrude outward from the side surface of the reflective layer 190.

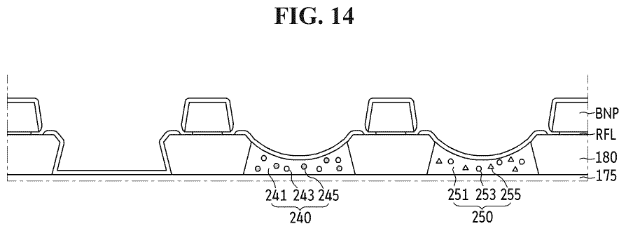

Next, referring to FIG. 14, a first wavelength conversion pattern 240 is formed in an area corresponding to the second light emitting area LA2 (see FIG. 5) and a second wavelength conversion pattern 250 is formed in an area corresponding to the third light emitting area LA3 (see FIG. 5).

Subsequently, a capping material layer CPL is stacked entirely on the photo pattern BNP, the bank 180, the first wavelength conversion pattern 240, and the second wavelength conversion pattern 250. At this time, the capping material layer CPL may be separated by the undercut structure formed by the photo pattern BNP and the reflective layer 190 and stacked on the side portion of the reflective layer 190. That is, the capping material layer CPL may be stacked in a separate shape rather than being continuous. The capping material layer CPL may be formed to cover the first wavelength conversion pattern 240 and the second wavelength conversion pattern 250, and may be formed to cover an area of the second encapsulating inorganic film 175 corresponding to the first light emitting area LA1 (see FIG. 11).

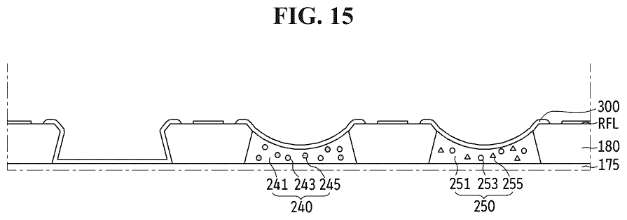

Next, referring to FIG. 15, the photo pattern BNP is stripped and removed. In an embodiment, for example, a stripper that can strip the photo pattern BNP is applied on the entire surface. The stripper may penetrate into the photo pattern BNP through a portion not covered by the capping material layer CPL due to the undercut structure formed by the photo pattern BNP and the reflective layer 190 to strip the photo pattern BNP. The capping layer 300 may be formed by removing a portion of the capping material layer CPL located on the photo pattern BNP along with the photo pattern BNP. Accordingly, the capping layer 300 may be formed in a separate or disconnected form on the bank 180.

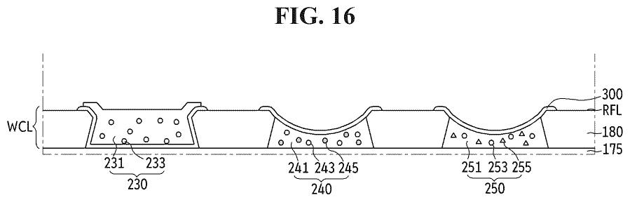

Subsequently, referring to FIG. 16, the reflective layer 190 is etched and removed. The etching process of the reflective layer 190 may be used as a wet etching process. In an embodiment, for example, the reflective layer 190 may be removed by applying an etchant on the entire surface.

Next, a wavelength conversion layer WCL is manufactured by forming a light transmission pattern 230 in an area corresponding to the first light emitting area LA1 (see FIG. 11).

According to an embodiment, as the first and second wavelength conversion patterns 240 and 250 are covered and protected by the capping material layer CPL before the strip process of the photo pattern BNP, it may be possible to effectively prevent the first and second wavelength conversion patterns 240 and 250 from being damaged from the strip process of the photo pattern BNP. In addition, due to the undercut structure between the photo pattern BNP and the reflective layer 190, the stripping of the photo pattern BNP may become easy even in a when the capping material layer CPL is formed.

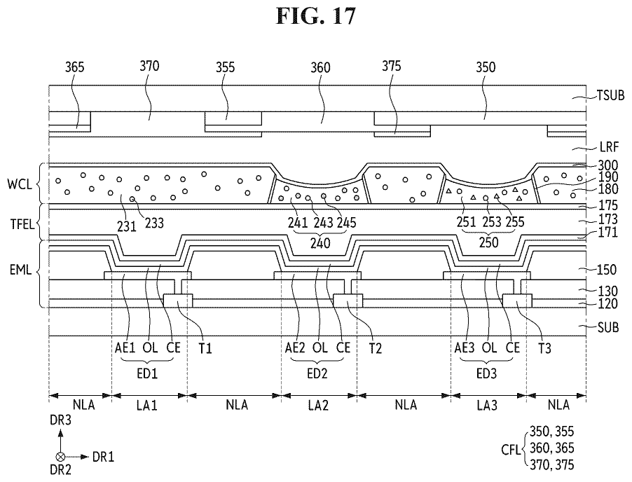

FIG. 17 is a cross-sectional view of a display device according to still another embodiment. For example, FIG. 17 shows another example of a structure in respect to the same portion of FIGS. 5 and 11.

The embodiment of FIG. 17 is substantially the same as the embodiment of FIG. 5 described above except that the bank 180 covers an area corresponding to the first light emitting area LA1 and the bank 180 is formed of a light transmitting material. Hereinafter, any repetitive detailed description of elements and features the same as those of FIG. 5 will be omitted or simplified, and differences will be described below.

In an embodiment, a bank 180 may be located on a thin-film encapsulation layer TFEL, and a first wavelength conversion pattern 240 may be formed in an area defined by the bank 180, for example, an area corresponding to the second light emitting area LA2, and a second wavelength conversion pattern 250 may be located in an area corresponding to the third light emitting area LA3.

In an embodiment, the bank 180 may be located in an area corresponding to the first light emitting area LA1, for example, in an area overlapping with the first light emitting area LA1. In an embodiment, for example, the bank 180 may be located to cover the thin-film encapsulation layer TFEL except for the area overlapping the second light emitting area LA2 and the third light emitting area LA3.

The bank 180 may include the material of the light transmission pattern described above. In an embodiment, for example, the bank 180 may include a first base resin 231 and first scatterers 233 dispersed in the first base resin 231. In an embodiment, the bank 180 including a transparent first base resin 231 and first scatters 233 may be formed to simultaneously serve as a light transmission pattern of the first light emitting area LA1. The bank 180 may transmit light emitted from a light emitting element layer EML.

A reflective layer 190 may be located on a side surface of the bank 180 and surround the first wavelength conversion pattern 240 and the second wavelength conversion pattern 250. As described above, in the case where the bank 180 is made of a transparent material, light may leak into an adjacent light emitting area and color mixing may occur. Accordingly, in an embodiment, the reflective layer 190 may be formed to surround the sides of the first wavelength conversion pattern 240 and the second wavelength conversion pattern 250, thereby effectively preventing the color mixing.

A capping layer 300 may be located on the bank 180, the first wavelength conversion pattern 240 and the second wavelength conversion pattern 250.

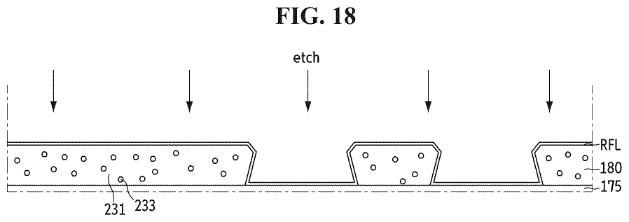

Hereinafter, a method of manufacturing a display device 10 shown in FIG. 17 will be described with reference to FIGS. 18 to 21. The overlapping description of the manufacturing methods of FIGS. 6 to 10 and FIGS. 12 to 16 will be briefly mentioned, and the differences will be mainly described.

FIGS. 18 to 21 are cross-sectional views illustrating a manufacturing method of a display device according to still another embodiment.

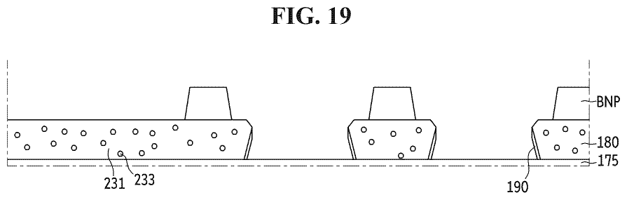

Referring to FIGS. 18 and 19, a bank 180 is formed on a second encapsulating inorganic film 175 of the thin-film encapsulation layer TFEL (see FIG. 17). The bank 180 may be manufactured by applying a bank material and using a photo process. In an embodiment, for example, the bank material including the first base resin 231 and the first scatterers 233 is entirely coated on the second encapsulating inorganic film 175 and then patterned using a photo process to form the bank 180. The bank 180 may be formed in a reverse tapered shape and entirely cover the remaining area except for the area corresponding to the second light emitting area LA2 (see FIG. 17) and the third light emitting area LA3 (see FIG. 17).

Next, after a reflective material layer RFL is stacked on the bank 180, an anisotropic dry etching process is executed, and a reflective layer 190 is formed on a side surface of the bank 180. Then, a photo pattern BNP is formed on the bank 180. The photo pattern BNP may be formed to surround an area corresponding to the second light emitting area LA2 (see FIG. 17) and the third light emitting area LA3 (see FIG. 17).

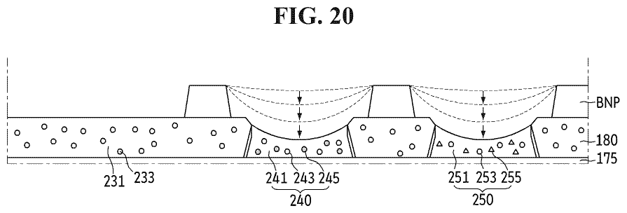

Subsequently, referring to FIG. 20, a first wavelength conversion pattern 240 is formed in an area corresponding to the second light emitting area LA2 (see FIG. 17) and a second wavelength conversion pattern 250 is formed in an area corresponding to the third light emitting area LA3 (see FIG. 17).

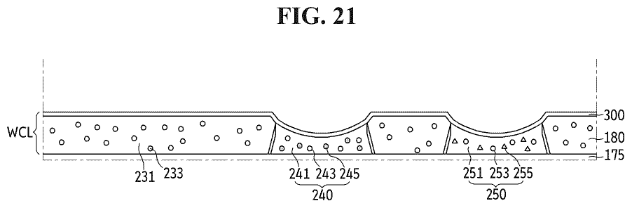

Next, referring to FIG. 21, a capping layer 300 is formed on the bank 180, the first wavelength conversion pattern 240, and the second wavelength conversion pattern 250 to manufacture a wavelength conversion layer WCL.

According to an embodiment, the manufacturing process may be simplified as the bank 180 including the first base resin 231 and the first scatterers 233 is formed to perform not only the role of the bank but also the role of the light transmission pattern. In addition, the reflective layer 190 may be formed to effectively prevent the color mixing due to the transparent bank layer 180.

The display device according to embodiments of the disclosure can be applied to various electronic devices. The electronic device according to embodiments of the disclosure includes the display device described above, and may further include modules or devices having additional functions in addition to the display device.

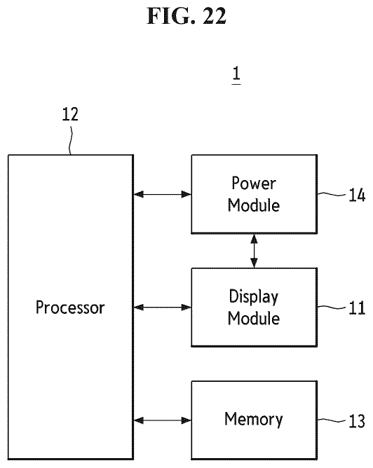

FIG. 22 is a block diagram of an electronic device according to an embodiment of the disclosure.

Referring to FIG. 22, the electronic device 1 according to an embodiment of the disclosure may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power used for the operation of the electronic device 1.

At least one selected from the components of the electronic device 1 according to an embodiment of the disclosure may be included in the display device 10 according to an embodiments of the disclosure. In addition, some modules of the individual modules functionally included in one module may be included in the display device 10, and other modules may be provided separately from the display device 10. In an embodiment, for example, the display device 10 may include the display module 11, and the processor 12, the memory 13, and the power module 14 may be provided in the form of other devices within the electronic device 1 other than the display device 10.

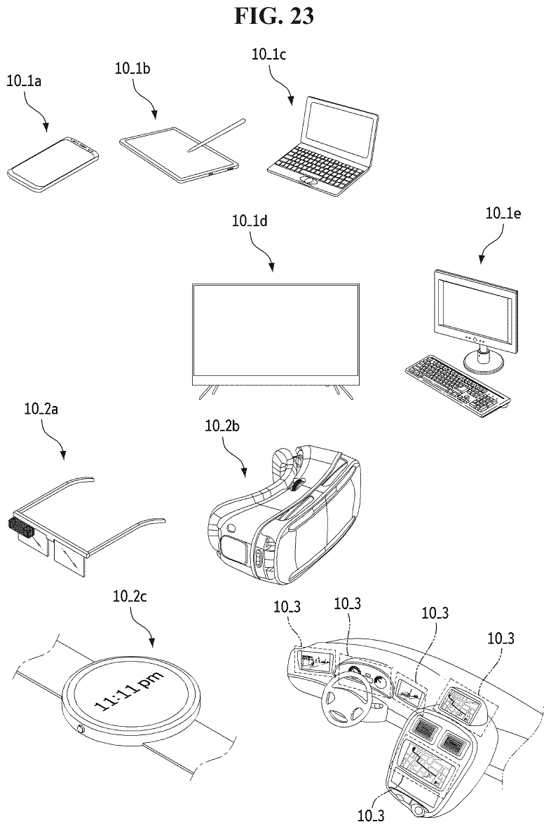

FIG. 23 is a schematic diagram of an electronic device according to various embodiments of the disclosure.

Referring to FIG. 23, various electronic devices to which display devices 10 according to embodiments of the disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a center information display (CID) and a room mirror display arranged on a dashboard, center fascia, and dashboard of an automobile.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a light emitting element layer disposed on the substrate, wherein the light emitting element layer includes a first light emitting area, a second light emitting area, and a third light emitting area;
a thin-film encapsulation layer disposed on the light emitting element layer; and
a wavelength conversion layer disposed on the thin-film encapsulation layer,
wherein the wavelength conversion layer comprises:
a bank disposed on the thin-film encapsulation layer, wherein the bank exposes the first light emitting area, the second light emitting area, and the third light emitting area;
a light transmission pattern overlapping the first light emitting area, a first wavelength conversion pattern overlapping the second light emitting area, and a second wavelength conversion pattern overlapping the third light emitting area; and
a capping layer disposed on the bank, the first wavelength conversion pattern, and the second wavelength conversion pattern.

2. The display device of claim 1,
wherein the bank is in a reverse tapered shape.

3. The display device of claim 1,
wherein the bank includes an organic material and at least one selected from a light blocking dye or pigment.

4. The display device of claim 1, further comprising:
a reflective layer disposed on a side surface of the bank,
wherein the reflective layer is in contact with the side surface of the bank, and is in contact with a side surface of each of the light transmission pattern, the first wavelength conversion pattern, and the second wavelength conversion pattern.

5. The display device of claim 1,
wherein a thickness of the light transmission pattern is greater than a thickness of the bank, and
a thickness of each of the first wavelength conversion pattern and the second wavelength conversion pattern is smaller than the thickness of the bank.

6. The display device of claim 4,
wherein the first wavelength conversion pattern and the second wavelength conversion pattern are in contact with the reflective layer and not in contact with the bank.

7. The display device of claim 1,
wherein the light transmission pattern comprises a first base resin and a first scatter,
the first wavelength conversion pattern comprises a second base resin, a second scatterer, and a first wavelength shifter,
the second wavelength conversion pattern comprises a third base resin, a third scatterer, and a second wavelength shifter, and
wherein each of the first wavelength shifter and the second wavelength shifter changes light emitted from the light emitting element layer into light of a different color.

8. The display device of claim 1, further comprising:
a counter substrate disposed opposite to the substrate;
a color filter layer disposed on the counter substrate, wherein the color filter layer includes a first color filter overlapping the first light emitting area, a second color filter overlapping the second light emitting area, and a third color filter overlapping the third light emitting area; and
a filling layer disposed between the color filter layer and the wavelength conversion layer.

9. The display device of claim 1,
wherein the capping layer disposed on the light transmission pattern.

10. The display device of claim 1,
wherein the capping layer disposed between the light transmission pattern and the thin-film encapsulation layer.

11. The display device of claim 10,
wherein the capping layer is divided into portions separated and spaced apart from each other on the bank.

12. The display device of claim 10,
wherein the light transmission pattern is disposed directly on the capping layer, and is not in direct contact with the bank.

13. The display device of claim 10,
wherein the bank is in a reverse tapered shape.

14. The display device of claim 10,
wherein the bank includes an organic material and at least one selected from a light blocking dye or pigment.

15. A display device comprising:
a substrate;
a light emitting element layer disposed on the substrate, wherein the light emitting element layer includes a first light emitting area, a second light emitting area, and a third light emitting area;
a thin-film encapsulation layer disposed on the light emitting element layer; and
a wavelength conversion layer disposed on the thin-film encapsulation layer,
wherein the wavelength conversion layer comprises:
a bank disposed on the thin-film encapsulation layer, overlapping the first light emitting area, wherein the bank exposes the second light emitting area and the third light emitting area;
a reflective layer disposed on a side surface of the bank;
a first wavelength conversion pattern overlapping the second light emitting area and a second wavelength conversion pattern overlapping the third light emitting area; and
a capping layer disposed on the bank, the first wavelength conversion pattern, and the second wavelength conversion pattern,
wherein the bank includes a first base resin and a first scatterer.

16. The display device of claim 15,
wherein the bank transmits light emitted from the light emitting element layer.

17. The display device of claim 15,
wherein the reflective layer is in contact with the side surface of the bank, and is in contact with a side surface of each of the first wavelength conversion pattern and the second wavelength conversion pattern.

18. The display device of claim 15,
wherein the first wavelength conversion pattern and the second wavelength conversion pattern is in contact with the reflective layer and not in contact with the bank.

19. The display device of claim 15, further comprising:
a counter substrate disposed opposite to the substrate;
a color filter layer disposed on the counter substrate, wherein the color filter layer includes a first color filter overlapping the first light emitting area, a second color filter overlapping the second light emitting area, and a third color filter overlapping the third light emitting area; and
a filling layer disposed between the color filter layer and the wavelength conversion layer.

20. An electronic device, comprising:
a display device which provides an image; and
a processor which provides an image data signal to the display device, and
wherein the display device comprises:
a substrate;
a light emitting element layer disposed on the substrate, wherein the light emitting element layer includes a first light emitting area, a second light emitting area, and a third light emitting area;
a thin-film encapsulation layer disposed on the light emitting element layer; and
a wavelength conversion layer disposed on the thin-film encapsulation layer, wherein the wavelength conversion layer comprises:
a bank disposed on the thin-film encapsulation layer, wherein the bank exposes the first light emitting area, the second light emitting area, and the third light emitting area;
a reflective layer disposed on a side surface of the bank;
a light transmission pattern overlapping the first light emitting area, a first wavelength conversion pattern overlapping the second light emitting area, and a second wavelength conversion pattern overlapping the third light emitting area; and
a capping layer disposed on the bank, the light transmission pattern, the first wavelength conversion pattern, and the second wavelength conversion pattern.
